(19) United States
(12) Patent Application Publication
(10) Pub. No.: US 2015/0070958 A1
(43) Pub. Date: Mar. 12, 2015

(54) LINE LAYOUT FOR SEMICONDUCTOR MEMORY APPARATUS

(71) Applicant: SK hynix Inc., Icheon-si Gyeonggi-do (KR)

(72) Inventor: Seol Hee LEE, Icheon-si Gyeonggi-do (KR)

(73) Assignee: SK hynix Inc,, Icheon-si Gyeonggi-do (KR)

(21) Appl. No.: 14/100,130

(22) Filed: Dec. 9, 2013

(30) Foreign Application Priority Data
Sep. 6, 2013 (KR) 10-2013-0107237

(51) Int. Cl. G11C 5/06

(52) U.S. Cl. CPC G11C 5/063
USPC 365/53; 365/63

(57) ABSTRACT

Provided is a line layout for a semiconductor memory apparatus, which is a line layout of a line layer formed over a memory region so as to cross the memory region. The line layout includes as unit lines: a data line disposed between a pair of shielding lines; a pair of address line groups disposed at one side of the shielding lines; and a power supply line disposed between the pair of address line groups.

### CROSS-REFERENCES TO RELATED APPLICATION

The present application claims priority under 35 U.S.C. §119(a) to Korean application number 10-2013-0107237, filed on Sep. 6, 2013, in the Korean Intellectual Property Office, which is incorporated herein by reference in its entirety.

### BACKGROUND

1. Technical Field

Various embodiments relate to a semiconductor apparatus, and more particularly, to a line layout for a semiconductor memory apparatus.

2. Description of Related Art

The integration degree, capacity, and speed of semiconductor memory apparatuses have continuously increased. In particular, various attempts have been made to implement a semiconductor memory apparatus having a higher capacity within a limited area.

FIG. 1 is a layout diagram of a conventional semiconductor memory apparatus, illustrating an 8F2 layout.

At the respective intersections between word lines WL arranged in one direction and bit lines LB arranged to cross the word lines WL, a plurality of memory cells are formed. In the 8F2 layout, the area of the unit memory cell occupies a size of 4F (F is minimum Feature size) in the extension direction of the word line WL and a size of 2F in the extension direction of the bit line BL.

FIG. 2 is another layout diagram of the conventional semiconductor memory apparatus, illustrating a 6F2 layout.

In the 6F2 layout, a unit memory cell is formed within a size of 3F in the extension direction of a word line WL and a size of 2F in the extension direction of a bit line BL. Since the 6F2 layout includes a larger number of memory cells formed in the same area than the 8F2 layout, the 6F2 layout has an advantage in a high capacity and a reduction in size.

In the case of the 8F2 layout, the unit memory cell occupies a sufficient area. Thus, various types of lines may be disposed over the memory cells, while securing a width and interval required by the design rule. Thus, the 8F2 layout has an advantage in securing a process margin and a design characteristic.

In the 6F2 layout, the pitch of the line must be reduced by the reduction in area occupied by the unit memory cell.

FIG. 3 is a configuration diagram of the conventional semiconductor memory apparatus.

The semiconductor memory apparatus may include one or more banks 110, 120, 130 and 140. Each of the banks 110, 120, 130 and 140 may include a plurality of unit memory cell arrays 100 and decoders X-DEC and Y-DEC configured to select a memory cell according to an address of the memory to be accessed.

At one side of the banks 110, 120, 130 and 140, a peripheral circuit region 150 is disposed. The peripheral circuit region 150 may include an address/command processing unit, a data input/output processing unit, a voltage supply unit and the like. Furthermore, a bonding pad, a probing pad and the like may be disposed in the peripheral circuit area 150.

FIG. 4 illustrates the detailed configuration of the unit memory cell array 100.

The unit memory cell array 100 includes a memory region 101, a word line decoder/driver 130 formed at one side of the memory region 101 in the extension direction of the word line WL, a bit line sense amplifier 105 formed at another side of the memory region 101 in the extension direction of the bit line BL, and a drive/control region 107.

M1 schematically represents lines formed at a lower layer, and a word line enable signal line, a local data input/output line and the like may be implemented through the lines M1 formed at the lower layer.

M2 schematically represents lines formed at a first layer over the lower layer. The lower layer and the first layer are insulated from each other by an interlayer dielectric layer. The lines M2 formed at the first layer may include a global data input/output line, a power supply line, an address line and the like. Furthermore, as illustrated in FIG. 4, the lines M2 at the first layer are formed over the memory region 101 so as to cross the memory area 101.

In the 8F2 layout, address lines and power supply lines may be disposed at the M2 line layer over the memory area 101. FIG. 5 illustrates such an example.

Referring to FIG. 5, the unit lines formed at the M2 line layer over the memory region 101 in the 8F2 layout includes a plurality of address lines A11, A12, A13 and A14 and one power supply line PWR11. The address lines A11, A12, A13 and A14 are coupled to the lines M1 at the lower layer through a plurality of contacts C11, C12, C13 and C14, respectively.

The power supply line PWR11 is configured to receive power generated from the peripheral circuit region and provide the received power to various internal circuits.

In the 8F2 layout, the pitches W11 and W12 of the address lines A11, A12, A13 and A14 and the power supply line PWR11 sufficiently satisfy a size required by the design rule.

In the 6F2 layout, however, necessary lines must be formed within a smaller area than in the 8F2 layout. Furthermore, a data line (global data input/output line) and a shielding line must be disposed in the M2 line layer over the memory region, in addition to the address lines and the power line. Thus, the M2 line pattern may become complex, and the width of the lines and the interval between the lines may be reduced to thereby make it difficult to secure a process margin and a design characteristic.

### SUMMARY

In an embodiment of the invention, there is provided a line layout for a semiconductor memory apparatus, which is a line layout of a line layer formed over a memory region so as to cross the memory region. The line layout includes as unit lines: a data line disposed between a pair of shielding lines; a pair of address line groups disposed at one side of the shielding lines; and a power supply line disposed between the pair of address line groups.

In an embodiment of the invention, there is provided a line layout for a semiconductor memory apparatus, which is a line layout of a first line layer formed over a memory region so as to cross the memory region and a second line layer formed over the first line layer. The first line layer comprises a power supply line disposed at one side of an address line group, as unit lines, and the second line layer comprises a data line.

In an embodiment of the invention, a line layout comprising as unit lines: a data line disposed between a plurality of shielding lines; a plurality of address line groups disposed on at least one side of the plurality of shielding lines; and a power supply line disposed between a plurality of address lines.

### BRIEF DESCRIPTION OF THE DRAWINGS

Features, aspects, and embodiments are described in conjunction with the attached drawings, in which:

FIG. 1 is a layout diagram of a conventional semiconductor memory apparatus;

FIG. 2 is another layout diagram of the conventional semiconductor memory apparatus;

FIG. 3 is a configuration diagram of the conventional semiconductor memory apparatus;

FIG. 4 is a configuration diagram of a unit memory cell array of the conventional semiconductor memory apparatus;

FIG. 5 is a diagram for explaining a line layout for the semiconductor memory apparatus of FIG. 1;

FIG. 6 is a diagram for explaining a line layout for a semiconductor memory apparatus according to an embodiment of the invention; and

FIGS. 7 and 8 are diagrams for explaining a line layout for a semiconductor memory apparatus according to an embodiment of the invention.

FIG. 9 is a block diagram of an embodiment of the invention.

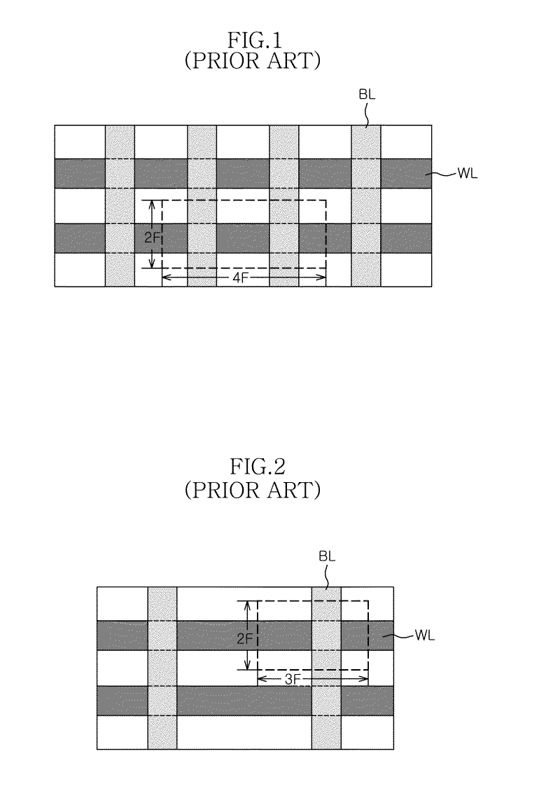

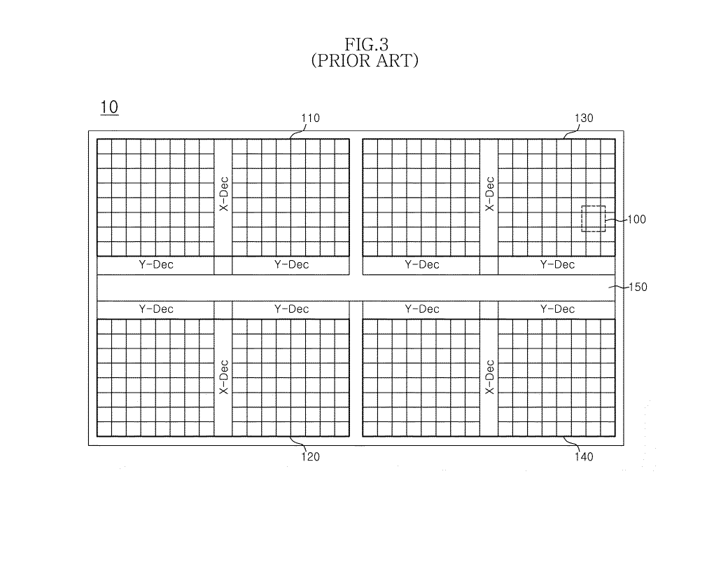

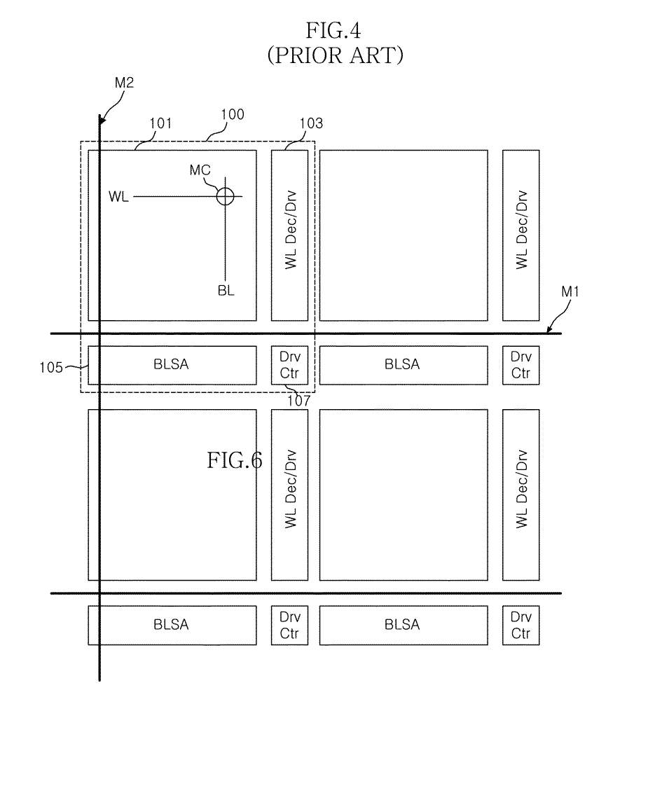

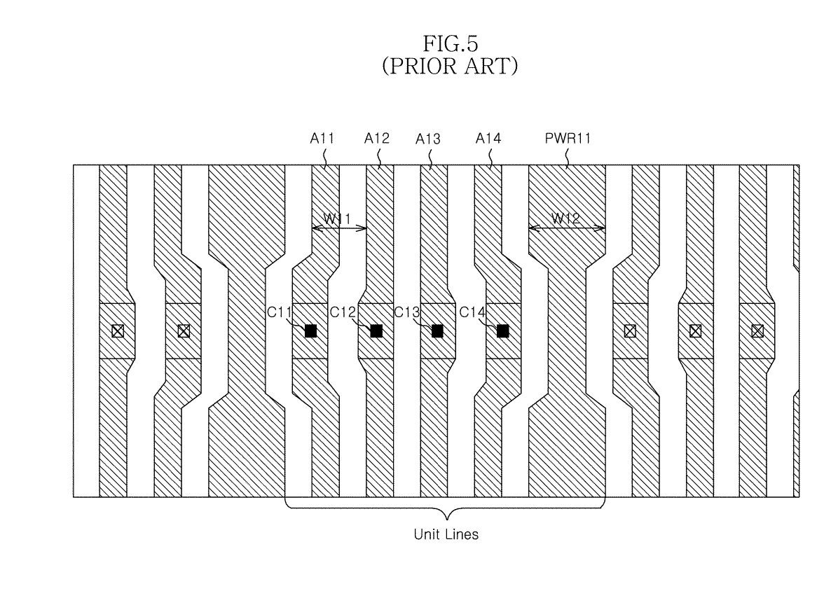

### DETAILED DESCRIPTION

Hereinafter, a line layout for a semiconductor memory apparatus according to the invention will be described below with reference to the accompanying drawings through various embodiments.

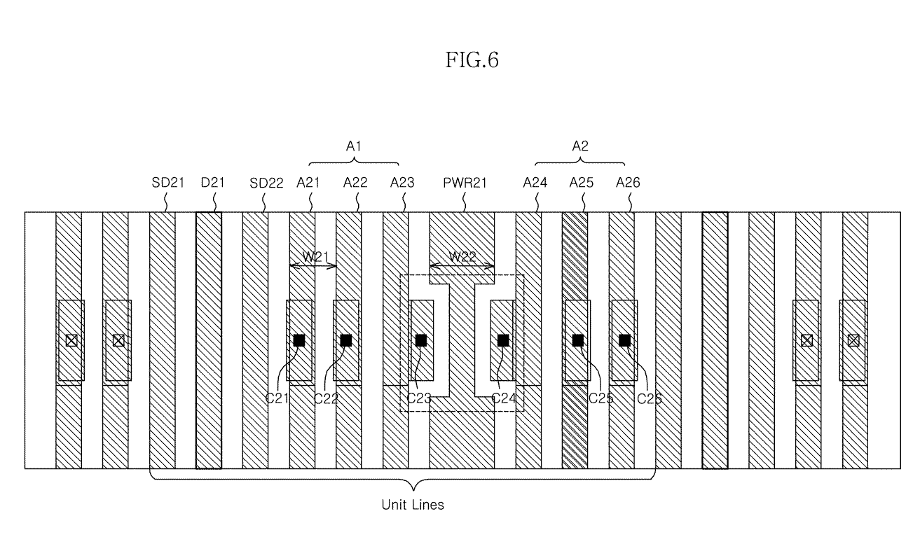

FIG. 6 is a diagram for explaining a line layout for a semiconductor memory apparatus according to an embodiment of the invention.

A semiconductor substrate includes a bank region and a peripheral circuit region, which are formed thereon. The bank region includes a plurality of unit memory cell arrays and a decoding circuit for accessing a unit memory cell array, and the peripheral circuit region is formed around the bank region.

An upper layer of a peripheral circuit unit of the peripheral circuit region in a vertical direction may be referred to as a lower layer, and a lower line layer is formed at the lower layer.

A first layer may include an upper layer positioned over the lower layer in a vertical direction, and may be formed over a memory region so as to cross the memory region. The first layer may include a data line (for example, global data input/output line), a power supply line, an address line and the like, and the lines of the first layer may be formed over the memory region so as to cross the memory region. FIG. 6 illustrates such a line layout at the first layer.

Referring to FIG. 6, the line layout according to an embodiment of the invention includes a pair of shielding lines SD21 and SD22, a data line D21 disposed between the pair of shielding lines, a pair of address line groups A1 and A2 disposed at one side of any one of the shielding lines SD21 and SD22, and a power supply line PWR21 disposed between the pair of address line groups A1 and A2, as unit lines.

The unit lines may be repetitively disposed at the first line layer by a required number.

Each of the address line groups A1 and A2 may include one or more address lines A21, A22, and A23 or A24, A25, and A26.

Each of the address lines A21, A22, and A23 or A24, A25, and A26 has a smaller pitch W21 than in the 8F2 layout, and also a smaller pitch W21 than that of the power supply line PWR11 as illustrated in FIG. 6. That is, each of the address lines A21, A22, and A23 or A24, A25, and A26 is formed to have a smaller pitch than the pitch W11 of the address lines A11, A12, A13 and A14 of FIG. 5. FIG. 6 also illustrates a pitch W21 and address contacts C21, C22, C23, C24, C25, and C26. On the other hand, the power supply line PWR21 is formed to have a larger pitch W22 than the power supply line PWR11 of FIG. 5, at a portion where the power supply line PWR21 has the greatest width. As illustrated in FIG. 6, the pitch W22 of the power supply line PWR11 is disposed between the address line groups A1 and A2. Thus, the power supply line PWR21 may supply sufficient power to the memory region.

In a general line layout for a semiconductor memory apparatus, the total pitch occupied by address lines is previously determined. In an embodiment, since the pitch of each of the address lines is reduced, any one of the address lines is formed to have an uneven structure including a protrusion, in order to satisfy the total pitch. In addition, the protrusion can be disposed between address contacts C23 and C24.

Referring to reference numeral 20 of FIG. 6, it can be seen that the address lines A23 and A24 disposed adjacent to the power supply line PWR21 are formed to have an uneven structure including a protrusion. Furthermore, the protrusion is extended to face the power supply line PWR21.

The power supply line PWR21 may be formed to have an uneven structure corresponding to the structure of the address lines A23 and A24. Since the maximum critical dimension (CD) or pitch W22 is secured, the uneven structure has no effect on power supply to the memory region. Each of the one or more address lines A21-A26 is electrically coupled to an address line of a lower layer through an address contact C21-C26.

In the 6F2 layout, since the unit memory cell has a small area, coupling may occur when an address line and a data line are disposed adjacent to each other. Thus, as illustrated in FIG. 6, the shielding line SD22 may be disposed between the address line group A1 and the data line D21 so as to suppress coupling.

As the unit lines are configured in such a manner, it is possible to improve a process margin and secure a design characteristic in the 6F2 layout in which the unit memory cell has a relatively small area. As the width of the power supply line is sufficiently secured, power may be smoothly supplied to the memory cell region.

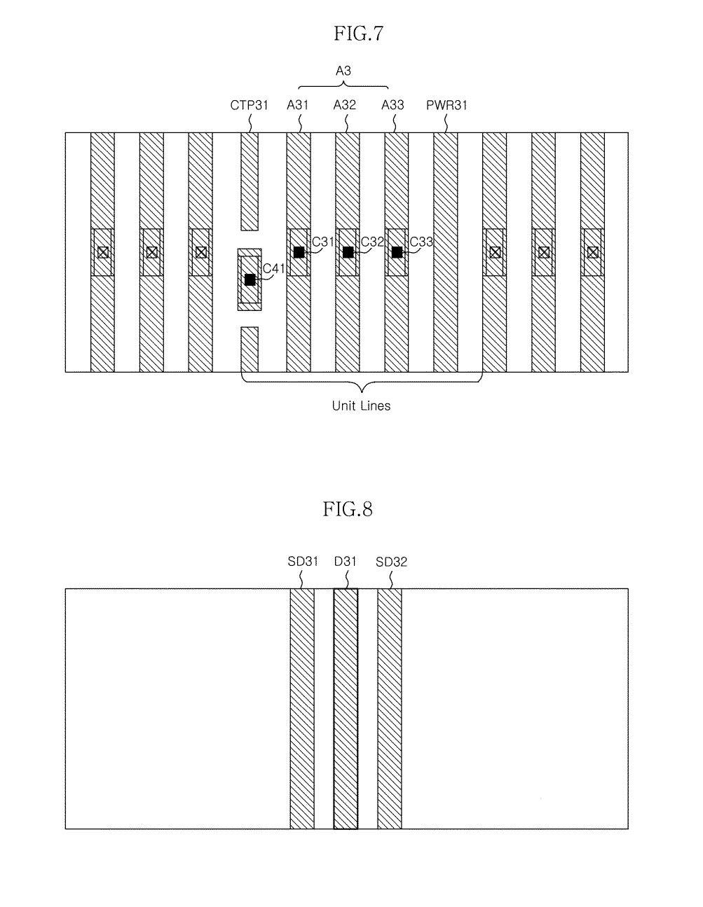

FIGS. 7 and 8 are diagrams for explaining a line layout for a semiconductor memory apparatus according to an embodiment of the invention.

The semiconductor memory apparatus not only may use a lower layer and a first line layer over the lower layer as line layers, but also may use a second line layer over the first line layer as an additional line layer. A line layer of a first line layer may be formed over a memory region in a vertical direction so as to cross the memory region and a second line layer formed over the first line layer in a vertical direction.

In the 6F2 layout, when three-level line layers are used, address lines and a power supply line may be disposed at the first line layer as illustrated in FIG. 7, and a data line and/or shielding lines may be disposed at the second layer.

Referring to FIG. 8, the first line layer may include an address line group A3 and a power supply line PWR31 formed at one side of the address line group A3, as unit lines.

The address line group A3 may include one or more address lines A31, A32 and A33. The address lines A31, A32 and A33 may be coupled to lines of the lower layer through address contacts C31, C32 and C33, respectively.

The power supply line PWR31 is coupled to a power supply line of the lower layer through a power supply contact C41. That is, the power supply contact C41 electrically couples the first layer and the lower layer, and transfers a voltage provided from the power supply line PWR31 to the lower layer. More specifically, the first line layer further comprises the power supply contact C41 electrically coupled to a lower layer of the first line layer. The power supply contact C41 may be formed at the other side of the address line group A3. In addition, the power supply line PWR31 is electrically coupled to the lower layer through the power supply contact.

Furthermore, a shield line CTP31 may be formed at both sides of the power supply contact C41 in a direction parallel to the extension direction of the address line group A3 and the power supply line PWR31. The shield line CTP31 may serve as a dummy pattern or shielding line, and may serve as a shielding line between the address lines A31, A32 and A33 formed at the first layer and the data line formed at the second line layer (refer to FIG. 8).

Referring to FIG. 8, the data line D31 is formed at the second line layer. In order to more fundamentally block coupling, shielding lines SD31 and SD32 may be employed. In this case, the data line D31 is disposed between the pair of shielding lines SD31 and SD32. In an embodiment of the invention, the shielding lines SD31 and SD32 may be omitted.

When the second line layer having the data line (and the shielding lines) disposed therein is employed in the 6F2 layout in which the unit memory cell has a small area, only the address lines and the power supply line are disposed at the first layer. Thus, the lines may be more efficiently disposed within a small area.

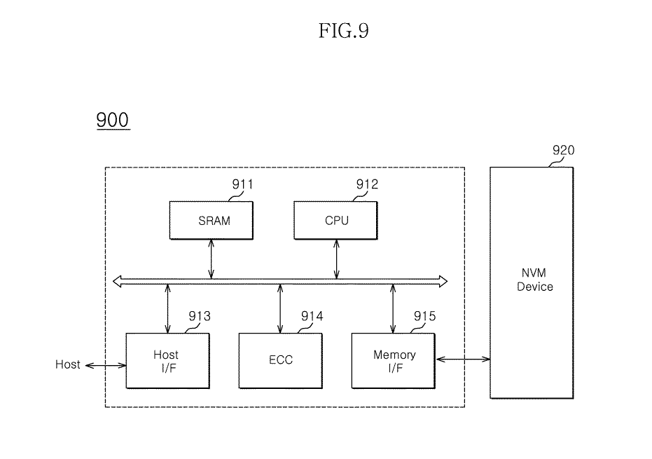

Referring to FIG. 9, a memory system 900 according to an embodiment of the invention may include a non-volatile memory device 920 and a memory controller 910.

The non-volatile memory device 920 may be configured to include the above-described semiconductor memory apparatus. The memory controller 910 may be configured to control the non-volatile memory device 920 in a general operation mode such as a program loop, a read operation or an erase loop.

The memory system 900 may be a solid state disk (SSD) or a memory card in which the memory device 920 and the memory controller 910 are combined. Static random-access memory (SRAM) 911 may function as an operation memory of a central processing unit (CPU) 912. A host interface 913 may include a data exchange protocol of a host being coupled to the memory system 900. An error correction code (ECC) block 914 may detect and correct errors included in a data read from the non-volatile memory device 920. A memory interface (I/F) 915 may interface with the non-volatile memory device 920. The CPU 912 may perform the general control operation for data exchange of the memory controller 910.

Though not illustrated in FIG. 9, the memory system 900 may further include read-only memory (ROM) that stores code data to interface with the host. In addition, the non-volatile memory device 920 may be a multi-chip package. The memory system 900 may be provided as a storage medium with a low error rate and high reliability. A memory system 900 such as a Solid State Disk (SSD), on which research has been actively carried out, may include a flash memory device according to an embodiment of the invention.

While certain embodiments have been described above, it will be understood to those skilled in the art that the embodiments described are by way of example only. Accordingly, the semiconductor memory apparatus described herein should not be limited based on the described embodiments. Rather, the semiconductor memory apparatus described herein should only be limited in light of the claims that follow when taken in conjunction with the above description and accompanying drawings.

What is claimed is:

1. A line layout for a semiconductor memory apparatus, which is a line layout of a line layer formed over a memory region so as to cross the memory region, the line layout comprising as unit lines:
a data line disposed between a pair of shielding lines;
a pair of address line groups disposed at one side of the shielding lines; and
a power supply line disposed between the pair of address line groups.

2. The line layout according to claim 1, wherein the unit lines are repetitively disposed at the line layer by a designated number.

3. The line layout according to claim 1, wherein each of the pair of address line groups comprises one or more address lines.

4. The line layout according to claim 3, wherein any one of the address lines has an uneven structure including a protrusion.

5. The line layout according to claim 4, wherein the address line having an uneven structure is disposed adjacent to the power supply line, and the protrusion is extended to face the power supply line.

6. The line layout according to claim 5, wherein the power supply line has an uneven structure corresponding to the address line having an uneven structure.

7. The line layout according to claim 3, wherein each of the one or more address lines is electrically coupled to an address line of a lower layer through an address contact.

8. A line layout for a semiconductor memory apparatus, which is a line layout of a first line layer formed over a memory region so as to cross the memory region and a second line layer formed over the first line layer,
Wherein the first line layer comprises a power supply line disposed at one side of an address line group, as unit lines, and
the second line layer comprises a data line.

9. The line layout according to claim 8, wherein the address line group comprises one or more address lines.

10. The line layout according to claim 9, wherein each of the one or more address lines is electrically coupled to an address line formed at a lower layer of the first line layer through an address contact.

11. The line layout according to claim 8, wherein the first line layer further comprises a power supply contact electrically coupled to a lower layer of the first line layer, and
the power supply line is electrically coupled to the lower layer through the power supply contact.

12. The line layout according to claim 11, wherein the first line layer further comprises a shield line formed at both sides of the power supply contact and extended in a direction parallel to an extension direction of the address line group and the power supply line.

13. The line layout according to claim 8, wherein the second line layer further comprises a pair of shielding lines formed at both sides of the data line.

14. A line layout for a semiconductor memory apparatus, the line layout comprising as unit lines:
a data line disposed between a plurality of shielding lines;
a plurality of address line groups disposed on at least one side of the plurality of shielding lines; and
a power supply line disposed between a plurality of address line groups.

15. The line layout according to claim 14, a plurality of address lines in each of the plurality of address line group is configured to have an uneven structure in response to a pitch for each of the plurality of address lines.

16. The line layout according to claim 14, wherein the power supply line is formed with an uneven structure and a secured pitch.

17. The line layout according to claim 14, wherein one or more of the plurality of shielding lines are disposed between one of the address line groups and the data line.

18. The line layout according to claim 14, wherein the pitch of the power supply line is disposed between the plurality of address line groups.

19. The line layout according to claim 14, wherein a plurality of address lines in each of the plurality of address line group are configured to have a smaller pitch than the power supply line.

20. The line layout according to claim 14, wherein a protrusion facing the power supply line is disposed between a plurality of address contacts.
